(19) United States
(12) Patent Application Publication
(10) Pub. No.: US 2004/0112293 A1
(43) Pub. Date: Jun. 17, 2004

(54) Semiconductor device production apparatus, and semiconductor device production method employing the same

(75) Inventor: Satofumi Kinei, Soraku-gun (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/730,358

(22) Filed: Dec. 9, 2003

(30) Foreign Application Priority Data
Dec. 10, 2002 (JP) 2002-358055
Oct. 24, 2003 (JP) 2003-365002

(51) Int. Cl. C23C 16/00

(52) U.S. Cl. 118/725; 118/728

(57) ABSTRACT

A semiconductor device production apparatus includes a rotary table section including a rotary table for supporting a wafer thereon, a chamber for housing the rotary table section, a heater provided in the chamber for heating the wafer, a temperature sensing device for sensing a temperature of the wafer, a temperature measuring section for converting the sensed temperature into a first signal to output the first signal, and a signal generating section for converting the output first signal into a second signal detectable from outside the chamber.

The temperature sensing device, the temperature measuring section and the signal generating section are attached to the rotary table section.

### CROSS-REFERENCE TO RELATED APPLICATION

This application is related to Japanese patent application Nos. 2002-358055 filed on Dec. 10, 2002 and 2003-365002 filed on Oct. 24, 2003, whose priorities are claimed under 35 USC §119, the disclosures of which are incorporated by reference in their entirety.

### BACKGROUND OF THE INVENTION

1. Field of the Invention

The present invention relates to an apparatus for producing a semiconductor device and, particularly, to a semiconductor device production apparatus such as a CVD apparatus, a vapor deposition apparatus, a dry etching apparatus or an ion implantation apparatus.

2. Description of the Related Art

A prior-art semiconductor device production apparatus related to the present invention is disclosed, for example, in Japanese Unexamined Utility Model Publication No. Hei 4-121734 (1992). This semiconductor device production apparatus is adapted to plasma-etch a wafer placed on a lower electrode having cooling means. The apparatus includes an infrared temperature meter embedded in a wall of an etching chamber in opposed relation to the wafer in the chamber for measuring the temperature of the wafer in a non-contact manner, and a temperature controller for controlling the temperature of a coolant on the basis of a signal from the temperature meter to keep the wafer temperature at a predetermined level.

In a semiconductor device production apparatus such as a CVD apparatus, a vapor deposition apparatus, a dry etching apparatus or an ion implantation apparatus, a wafer is generally placed on a rotary table so that the wafer can evenly receive heat from a heater for uniform film formation. In such an apparatus, the temperature of the wafer is an important control factor which determines film formation characteristics. Therefore, the film formation characteristics can stably be provided by controlling the output of the heater on the basis of the measurement of the wafer temperature. However, where the wafer temperature is measured in a non-contact manner by means of the infrared temperature meter as in the prior art, a window through which an infrared beam is received from the meter is often blurred or dirtied with dust. This makes it difficult to accurately measure the wafer temperature.

### SUMMARY OF THE INVENTION

In view of the foregoing, the present invention is directed to a semiconductor device production apparatus which is capable of measuring a wafer temperature by means of a temperature sensing device provided in a rotary table section for accurately controlling a heater output, and to a semiconductor device production method employing the apparatus.

The present invention provides a semiconductor device production apparatus, which comprises: a rotary table section including a rotary table for supporting a wafer thereon; a chamber for housing the rotary table section; a heater provided in the chamber for heating the wafer; a temperature sensing device for sensing a temperature of the wafer; a temperature measuring section for converting the sensed temperature into a first signal to output the first signal; and a signal generating section for converting the output first signal into a second signal detectable from outside the chamber; wherein the temperature sensing device, the temperature measuring section and the signal generating section are attached to the rotary table section.

According to the present invention, the wafer temperature is sensed by the temperature sensing device provided in the rotary table and converted into the signal detectable from outside the chamber, and the detectable signal is outputted. Therefore, a heater output can accurately be controlled on the basis of the signal detected outside the chamber. Thus, the wafer temperature can properly be controlled.

### BRIEF DESCRIPTION OF THE DRAWINGS

FIG. 1 is an explanatory diagram illustrating the construction of an apparatus according to a first embodiment of the present invention;

FIG. 2 is an enlarged diagram of a major portion of the apparatus shown in FIG. 1;

FIG. 3 is an explanatory diagram illustrating the construction of an apparatus according to a second embodiment of the present invention; and

FIG. 4 is an explanatory diagram illustrating the construction of an apparatus according to a third embodiment of the present invention.

### DETAILED DESCRIPTION OF THE INVENTION

A semiconductor device production apparatus according to the present invention comprises: a rotary table section including a rotary table for supporting a wafer thereon; a chamber for housing the rotary table section; a heater provided in the chamber for heating the wafer; a temperature sensing device for sensing a temperature of the wafer; a temperature measuring section for converting the sensed temperature into a first signal to output the first signal; and a signal generating section for converting the output first signal into a second signal detectable from outside the chamber; wherein the temperature sensing device, the temperature measuring section and the signal generating section are attached to the rotary table section.

In the present invention, the wafer may be a highly pure Si wafer or InP wafer which is generally used in a semiconductor device production process. The rotary table section may include a disk on which a plurality of wafers are placed circumferentially thereof, a shaft which rotatably supports the disk, and a drive source which is mechanically coupled to the shaft for rotation of the disk.

In the present invention, the temperature sensing device may be a thermocouple or a temperature sensing resistor, and is properly selected depending on a measurement temperature range. More specifically, a K-thermocouple is preferably employed for a temperature range below 100° C., and a temperature sensing resistor is preferably employed for a temperature range below 500° C.

Where the thermocouple is employed as the temperature sensing device in the present invention, the temperature measuring section includes, for example, a cold contact compensation circuit, a linearizer and a DC amplifier.

The signal generating section which converts the output of the temperature measuring section into the signal detectable from outside the chamber and outputs the detectable signal may comprise a wireless transmitter which modulates the output of the temperature measuring section, for example, on an analog or digital basis and transmits the modulated output in the form of a radio wave signal. Alternatively, the signal generating section may comprise an infrared transmitter which converts the output of the temperature measuring section into an infrared signal and transmits the infrared signal, a display device which displays a color or a symbol converted correspondingly from the output (temperature) of the temperature measuring section, or a storage device which stores the output of the temperature measuring section as temperature profile data in a flash memory.

Where the signal generating section comprises the wireless transmitter, a receiver and a heater controlling section are further provided outside the chamber to feedback-control the heater on the basis of a wireless signal received by the receiver.

Where the signal generating section comprises the infrared transmitter, an infrared receiver and a heater controlling section are further provided outside the chamber to feedback-control the heater on the basis of an infrared signal received by the infrared receiver.

Where the signal generating section comprises the display device, an operator may manually control the heater on the basis of information displayed on the display device.

Where the signal generating section comprises a detachable storage device such as a flash memory which stores the output of the temperature measuring section, the storage device may be taken out of the chamber after completion of a heat treatment so that a heater temperature setting program is modified on the basis of a temperature profile read out of the storage device.

A micro-drive which is one type of magnetic disks may be used as the detachable storage device. Since the micro-drive has a greater storage capacity than the flash memory, it is possible to construct a system suitable for a production apparatus which requires a complicated control such as a multi-step temperature program control or a temperature gradation control in a semiconductor device production apparatus having a multiplicity of temperature sensing devices.

The inventive semiconductor device production apparatus preferably further comprises a cooling section for cooling the temperature measuring section and the signal generating section.

Further, a driving power source (e.g., a battery cell or a battery) may be incorporated in the temperature measuring section and the signal generating section.

The heater provided in the chamber is preferably capable of heating the wafer up to a temperature of 600 to 800° C. In this case, a resistive heat generator is advantageously employed as the heater. Examples of the resistive heat generator include metal heat generators such as Fe—Cr—Al alloys (ferrite alloys), Ni—Cr—Fe alloys (austenite alloys) and platinum and tungsten (pure metals), and non-metallic heat generators such as SiC, MoSi₂, LaCrO₃ and graphite.

The chamber preferably has an inlet through which a material gas required for the semiconductor device production process is introduced into the chamber.

According to another aspect of the present invention, there is provided a production method for a semiconductor device, which employs the semiconductor device production apparatus described above and comprises the steps of: placing a wafer on the rotary table; heating the wafer by the heater; supplying a material gas into the chamber; detecting the second signal outside the chamber; and controlling the heater on the basis of the detected second signal for production of a semiconductor device.

Embodiments

With reference to the attached drawings, the present invention will hereinafter be described in detail by way of embodiments thereof. However, it should be understood that the invention be not limited to these embodiments.

First Embodiment

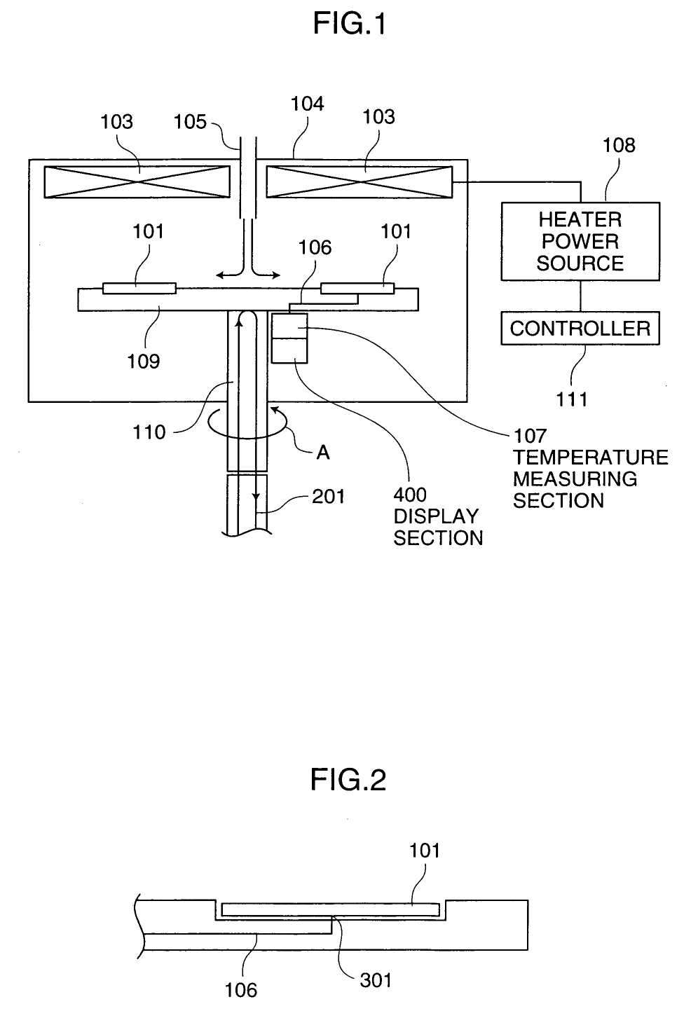

FIG. 1 is an explanatory diagram illustrating the construction of an MOCVD apparatus according to a first embodiment of the present invention which employs an In-based material.

As shown, a rotary disk 109 is housed in a cylindrical chamber 104, and a plurality of wafers 101 are mounted on an upper surface of the rotary disk 109. The rotary disk 109 is horizontally supported at its center on a hollow shaft 110 from a lower side. The hollow shaft 110 is mechanically coupled to a motor not shown. The rotary disk 109 is horizontally rotated in an arrow direction A by the motor.

Further, the chamber 104 has a peripheral wall which has a transparent portion for observation of the inside thereof from the outside thereof. A thermocouple 106 is embedded in the rotary disk 109. As shown in FIG. 2, a distal end 301 of the thermocouple 106 projects from the surface of the disk 109 so as to be brought into close relation to or into contact with a rear surface of one of the wafers 101.

Although the In-based material is generally liable to be decomposed, an In-based gas introduced through a material gas inlet 105 should be decomposed in the vicinity of the wafers 101. Therefore, cooling water 201 is circulated in the hollow shaft 110 to cool a rear center portion of the rotary disk 109 for suppression of temperature increase of the material gas introduced to a front center portion of the rotary disk 109.

A temperature measuring section 107 and a display section 400 are provided in the vicinity of the hollow shaft 110 below the rotary disk 109, and cooled by the cooling water 201. The temperature measuring section 107 is adapted to convert the thermoelectric voltage of the thermocouple 106 into temperature data which is directly proportional to a measured temperature. The display section 400 is adapted to convert the temperature data from the measuring section 107 into display data and display the measured temperature. The temperature measuring section 107 and the display section 400 are each driven by a built-in battery.

A heater 103 of a resistive heat generator is provided in the vicinity of the ceiling of the chamber 104, and electrically connected to a heater power source 108 provided outside the chamber 104. The heater power source 108 is connected to a manual controller 111, so that an operator can control the output of the heater 103 by operating the controller 111. Further, the material gas inlet 105 is provided in a center portion of the ceiling of the chamber 104.

The display section 400 is constituted by an LCD or LED display device. With the aforesaid arrangement, the inside of the chamber 104 is heated by energizing the heater 103 by the heater power source 108. When the temperature of the wafer 101 displayed on the display device 400 reaches about 600° C., the rotary disk 109 is rotated. Then, the In material gas, e.g., trimethylindium (TMIn), is introduced into the chamber 104 through the material gas inlet 105 for a predetermined period, whereby thin films such as of InP are formed on the wafers 101.

During the film formation process, the operator manually controls the controller 111 so as to change the temperature of the wafers 101 in conformity with a predetermined temperature profile, while observing information displayed on the display section 400 through the transparent portion of the peripheral wall of the chamber 104. Thus, the In material films can be formed as having desired film characteristics.

Second Embodiment

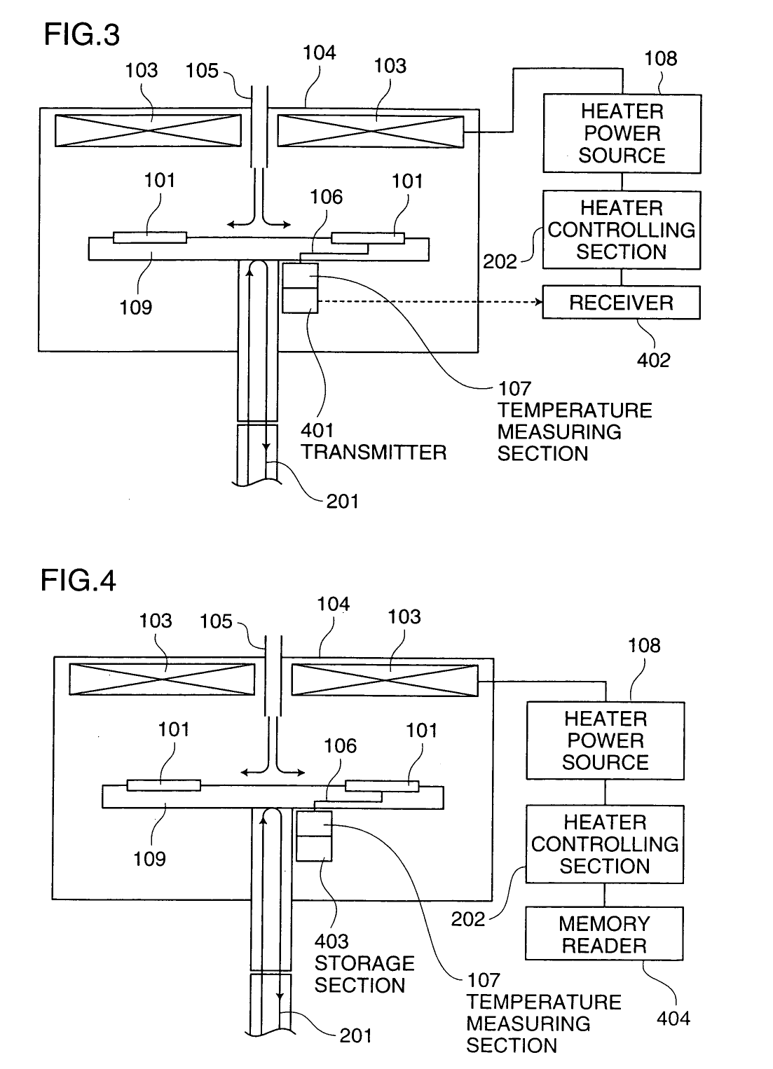

FIG. 3 is an explanatory diagram illustrating the construction of an MOCVD apparatus according to a second embodiment of the present invention.

The MOCVD apparatus shown in FIG. 3 has substantially the same construction as the apparatus according to the first embodiment, except that a wireless transmitter 401 is provided instead of the display section 400 shown in FIG. 1 and a wireless receiver 402 and a heater controlling section 202 are provided instead of the manual controller 109 shown in FIG. 1.

The transmitter 401 is adapted to encode the temperature data outputted from the temperature measuring section 107, modulate the encoded data on a digital basis at a codeless-phone frequency and transmit the modulated data in the form of a radio wave signal to the receiver 402. The receiver 402 is adapted to demodulate the radio wave signal received from the transmitter 401, decode the demodulated data and output the decoded data to the controlling section 202.

The controlling section 202 is constituted by a microprocessor including a CPU, a ROM and a RAM. The controlling section 202 is adapted to receive the output of the receiver 402 (i.e., the temperature data of the wafers 101) and feedback-control the output of the heater 103 via the heater power source 108 so that the temperature data of the wafers 101 conforms to a preset temperature profile preliminarily stored in the RAM. Thus, the temperature of the wafers 101 is controlled on the basis of the predetermined temperature profile.

Third Embodiment

FIG. 4 is an explanatory diagram illustrating the construction of an MOCVD apparatus according to a third embodiment of the present invention.

The MOCVD apparatus shown in FIG. 4 has substantially the same construction as the apparatus according to the second embodiment, except that a storage section 403 is provided instead of the transmitter 401 shown in FIG. 3 and a memory reader 404 is provided instead of the receiver 402. A memory card as a flash memory is removably housed in the storage section 403. The storage section 403 is capable of recording the temperature data outputted from the temperature measuring section 107 in the memory card.

With this arrangement, the heater controlling section 202 controls the output of the heater 103 via the heater power source 108 on an open-loop basis in conformity with the temperature profile preliminarily stored in the RAM when the film formation process is performed in the same manner as in the first embodiment.

Then, a measured temperature profile of the wafers 101 is stored in the memory card in the storage section 403. After completion of the film formation process, the operator takes out the memory card from the storage section 403, and loads the memory card in the memory reader 404. The memory reader 404 reads out the measured temperature profile from the memory card. The controlling section 202 compares the measured temperature profile with the temperature profile stored in the RAM, and modifies a heater output controlling program stored in the RAM so that these temperature profiles conform to each other. By repeating this operation, the temperature of the wafers 101 is controlled on the basis of the predetermined temperature profile.

What is claim d is:

1. A semiconductor device production apparatus comprising:
a rotary table section including a rotary table for supporting a wafer thereon;
a chamber for housing the rotary table section;
a heater provided in the chamber for heating the wafer;
a temperature sensing device for sensing a temperature of the wafer;
a temperature measuring section for converting the sensed temperature into a first signal to output the first signal; and
a signal generating section for converting the output first signal into a second signal detectable from outside the chamber;
wherein the temperature sensing device, the temperature measuring section and the signal generating section are attached to the rotary table section.

2. A semiconductor device production apparatus as set forth in claim 1, wherein the temperature sensing device includes a thermocouple.

3. A semiconductor device production apparatus as set forth in claim 1, wherein the signal generating section comprises a detachable storage device for converting the first signal into a storage data to store the storage data as the second signal.

4. A semiconductor device production apparatus as set forth in claim 1, wherein the signal generating section comprises a wireless transmitter for converting the first signal into a wireless signal to transmit the wireless signal as the second signal.

5. A semiconductor device production apparatus as set forth in claim 1, wherein the signal generating section comprises a display device for converting the first signal into display data to display the display data as the second signal.

6. A semiconductor device production apparatus as set forth in claim 3, further comprising a storage data reader for read out the storage data from the storage device and a heater controlling section for controlling the heater on the basis of the read out storage data, the storage data reader and the heater controlling section being provided outside the chamber.

7. A semiconductor device production apparatus as set forth in claim 4, further comprising a receiver for receiving the wireless signal from the transmitter, and a heater controlling section for controlling the heater on the basis of the received signal, the receiver and the heater controlling section being provided outside the chamber.

8. A semiconductor device production method comprising the steps of:
providing a semiconductor device production apparatus as recited in claim 1;
placing a wafer on the rotary table;
heating the wafer by the heater;
supplying a material gas into the chamber;
detecting the second signal outside the chamber; and
controlling the heater on the basis of the detected second signal for production of a semiconductor device.
